(19) United States
(12) Patent Application Publication
(10) Pub. No.: US 2009/0038673 A1
(43) Pub. Date: Feb. 12, 2009

(54) Solar emergency power kit

(76) Inventor: Vernon Ware, Woodland, CA (US)

Correspondence Address: Vernon Ware, 165 Buckeye St., Woodland, CA, 95695, US

(21) Appl. No.: 11/890,854

(22) Filed: Aug. 8, 2007

(51) Int. Cl. H01L 31/042

(52) U.S. Cl. 136/246

(57) ABSTRACT

A portable power source kit is presented. The kit includes a lower box having a lower box volume, a storage battery contained in the lower box volume and an upper box having an upper box volume and attachable to the lower box. A power adapter is contained in the upper box volume. The power adapter includes at least one or more inputs and at least one or more outputs. The power adapter is electrically connected to the storage battery. A power inverter is contained in the upper box volume. The inverter is electrically connected to the storage battery for providing DC to AC power conversion. And, a solar panel assembly is electrically connected to the power adapter where the assembly provides power to the power adapter for use in charging the storage battery and delivering power to the one or more outputs.

### FIELD OF THE INVENTION

The present invention relates generally to solar power. More particularly, the invention relates to an emergency solar power kit.

### BACKGROUND OF THE INVENTION

Power outages may be caused by many occurrences such as, but not limited to, storms, earthquakes, accidents and power shortages, and emergency power is very desirable and sometimes necessary in these situations. Currently the main source of emergency power is provided by fuel-powered generators. People experiencing a power outage also often rely on candles for light. However, generators and candles have shortcomings. For example, without limitation, there is a risk of fire, and in the case of generators there are also issues such as, but not limited to, noise, fuel fumes and spills, carbon monoxide, and limited fuel capacity.

Portable power sources are also useful in other situations, for example, without limitation, outdoor activities such as camping. Furthermore, renewable power sources are highly desirable for environmental and economic reasons.

In view of the foregoing, there is a need for a clean, renewable and portable source for emergency and supplemental power.

### BRIEF DESCRIPTION OF THE DRAWINGS

The present invention is best illustrated by way of example, and not by way of limitation, in the figures of the accompanying drawings and in which like reference numerals refer to similar elements and in which:

FIG. 1 is a perspective view of an exemplary solar emergency power kit, in accordance with an embodiment of the present invention;

FIG. 2A is a schematic diagram of an exemplary solar panel assembly for a solar emergency power kit, in accordance with an embodiment of the present invention;

FIG. 2B illustrates an exemplary solar panel connection box of the solar panel assembly, in accordance with an embodiment of the present invention;

FIGS. 3A, 3B, 3C, and 3D are schematic diagrams of an exemplary upper box of a solar emergency power kit, in accordance with an embodiment of the present invention. FIG. 3A is a front view, FIG. 3B is a left end view, and FIG. 3C is a right end view. FIG. 3D illustrates a close up view of an exemplary positive wire harness and negative wire harness;

FIG. 4 illustrates exemplary wiring for the switch and receptacle of the upper box, in accordance with an embodiment of the present invention;

FIGS. 5A, 5B and 5C are schematic diagrams of an exemplary lower box of a solar emergency power kit, in accordance with an embodiment of the present invention;

FIG. 6 is a schematic diagram of an exemplary assembly of the upper box and lower box of a solar emergency power kit illustrating the connections between the devices in the upper box and the storage battery in the lower box, in accordance with an embodiment of the present invention; and

FIG. 7 is a top perspective view looking into an exemplary open solar emergency power kit illustrating exemplary storage options, in accordance with an embodiment of the present invention.

Unless otherwise indicated, illustrations in the drawings are not necessarily drawn to scale.

### SUMMARY OF THE INVENTION

To achieve the forgoing and other objects and in accordance with the purpose of the invention, a solar energy power kit is presented.

In one embodiment, a portable power source kit is presented. The kit includes a lower box having a lower box volume, a storage battery contained in the lower box volume and an upper box having an upper box volume and attachable to the lower box. A power adapter is contained in the upper box volume. The power adapter includes at least one or more inputs and at least one or more outputs. The power adapter is electrically connected to the storage battery. A power inverter is contained in the upper box volume. The inverter is electrically connected to the storage battery for providing DC to AC power conversion. And, a solar panel assembly is electrically connected to the power adapter where the assembly provides power to the power adapter for use in charging the storage battery and delivering power to the one or more outputs. In other embodiments, the kit further includes at least one or more DC power outlets and each of the one or more DC power outlets are connected to the storage battery via an outlet switch. In another embodiment, the kit further includes a clearance light electrically connected to the storage battery via a switch. In another embodiment, the switch is the outlet switch. In still another embodiment, the power inverter further includes at least one or more AC power outlets. In yet another embodiment, the power inverter is connected to the storage battery with clips for disconnecting when not in use to avoid power loss. In another embodiment, the power inverter further includes a power switch for activating the power outlets, an on indicator light and a low storage battery indicator. In other embodiments, the upper box volume includes a storage area for storing items, the lower box volume includes a storage area for storing items and the lower box has handles on an exterior of the lower box for transporting the kit.

In another embodiment a portable power source kit for emergency and supplemental use is presented. The kit includes means for storing power, means for containing the means for storing power, means for providing DC inputs and DC outputs, means for providing DC to AC power conversion, means for containing the means for providing DC inputs and DC outputs and the means for providing DC to AC power conversion, means for attaching the means for containing the means for storing power to the means for containing the means for providing DC inputs and DC outputs and the means for providing DC to AC power conversion, means for providing a solar panel assembly and means for electrically connecting the means for storing power, the means for providing DC inputs and DC outputs, the means for providing DC to AC power conversion and the means for providing a solar panel assembly where the solar panel assembly provides DC power, DC power is provided at the DC outputs, power can be stored in the means for storing power and the DC to AC power conversion can be operative. Another embodiment further includes means for providing handles for the kit. Yet another embodiment further includes means for providing storage of items.

In another embodiment, a portable power source kit for emergency and supplemental use is presented. The kit includes a lower box having a lower box volume, a storage battery contained in the lower box volume, an upper box having an upper box volume and attachable to the lower box. A power adapter is contained in the upper box volume. The power adapter includes at least one or more inputs and at least one or more outputs. The power adapter is electrically connected to the storage battery. At least one or more DC power outlets, the DC power outlets are connected to the storage battery via outlet switches. The DC power outlets are configured to provide DC power to standard AC devices that have been converted for DC use. A clearance light is electrically connected to the storage battery via a switch. A power inverter is contained in the upper box volume. The power inverter is electrically connected to the storage battery for providing DC to AC power conversion. The power inverter includes at least one or more AC power outlets, a power switch for activating the power inverter, an on indicator light and a low storage battery indicator. And, a solar panel assembly is electrically connected to the power adapter where the solar panel assembly provides power to the power adapter for use in charging the storage battery and delivering power to the one or more outputs. In another embodiment, the power inverter is connected to the storage battery with clips for disconnecting when not in use to avoid power loss. In another embodiment, the storage battery is a 12-volt deep cycle storage battery. In other embodiments, the upper box volume includes a storage area for storing items and the lower box volume includes a storage area for storing items. In still another embodiment, the lower box has handles on an exterior of the lower box for transporting the kit.

Other features, advantages, and object of the present invention will become more apparent and be more readily understood from the following detailed description, which should be read in conjunction with the accompanying drawings.

### DETAILED DESCRIPTION OF THE PREFERRED EMBODIMENTS

The present invention is best understood by reference to the detailed figures and the description set forth herein.

Embodiments of the invention are discussed below with reference to the Figures. However, those skilled in the art will readily appreciate that the detailed description given herein with respect to these figures is for explanatory purposes as the invention extends beyond these limited embodiments. For example, without limitation, it should be appreciated that those skilled in the art will, in light of the teachings of the present invention, recognize a multiplicity of alternate and suitable approaches, depending on the needs of the particular application, to implement the functionality of any given detail described herein, beyond the particular implementation choices in the following embodiments described and shown. That is, there are numerous modifications and variations of the invention that are too numerous to be listed but that all fit within the scope of the invention. Also, singular words should be read as plural and vice versa and masculine as feminine and vice versa, where appropriate, and alternative embodiments do not necessarily imply that the two are mutually exclusive.

The present invention will now be described in detail with reference to embodiments thereof as illustrated in the accompanying drawings.

The preferred embodiment of the present invention provides a solar panel device to be used as a renewable power source that can be used for power needs in a home, for example without limitation, emergency power or supplemental power. The preferred embodiment is designed to operate table lamps and other low wattage household items for short periods. However, alternate embodiments may be designed to power larger wattage items and/or for longer periods. The preferred embodiment is also portable, providing users with a portable power source for various activities such as, but not limited to, camping or other outdoor activities.

Embodiments of the present invention generally eliminate continuous generator noise, messy fuel spills and odors, and risk of fire that occur with traditional emergency power supplies. Also, unlike gas lighting, embodiments of the present invention have switches and thus do not need to run overnight. There are also no fears of carbon monoxides while operating embodiments of the present invention in enclosed areas such as, but not limited to, campers, tents, cabins, lento, workshops, sheds, patios, or any other enclosed shelters. Embodiments may be used in situations such as, but not limited to, camping trips or power outages, for recreation or due to events such as, but not limited to, storms or other disasters.

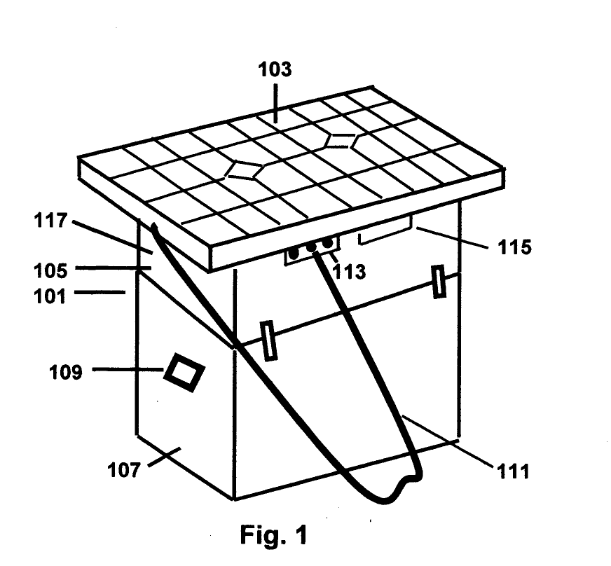

FIG. 1 is a perspective view of an exemplary solar emergency power kit 101, in accordance with an embodiment of the present invention. The present embodiment comprises a solar panel assembly 103, an upper box 105, and a lower box 107. Upper box 105 and lower box 107 are constructed of ½-inch plywood. The plywood is cut and formed into the boxes and secured with glue and finishing nails. In alternate embodiments the upper box and lower box may be constructed of various other materials such as, but not limited to, other types of wood or various plastics. In the present embodiment, upper box 105 is coupled to lower box 107 with a hinge to provide internal access. Handles 109 are located on each side of lower box 107 for carrying. The total weight of the present embodiment is approximately 70 lbs. when equipped with a 12-volt marine battery. A standard two-wire connecting cord 111 connects solar panel assembly 103 to an inlet/outlet power adapter 113. In the present embodiment, connecting cord 111 is 15 ft. to 20 ft long and is and indoor/outdoor type 16 gage 2 conducter. Some embodiments may use longer cords at a reduced efficiency. In the present embodiment, power adapter 113 is a 12-volt adapter with a power indicator light. The indicator light is lit when power adapter 113 is energized. For example, without limitation, during the day as solar panel assembly 103 is in use, the indicator light is lit; however if solar emergency power kit 101 is not plugged in at night, the indicator light is not lit. Leaving solar emergency power kit 101 plugged in enables the user to find it in complete darkness. Power adapter 113 also enables electrically powered objects such as, but not limited to, lamps and small appliances to be plugged into solar emergency power kit 101 so that they may be turned on. The present embodiment also comprises a clearance light 115. In the present embodiment, clearance light 115 is a 3-watt light used typically as a night light. Alternate embodiments may include smaller or larger clearance lights or multiple clearance lights, and other alternate embodiments may not include a clearance light.

Some embodiments may also include a framed cart with casters for convenience to move the solar emergency power kit from location to location if necessary. Other embodiments may have wheels such as, but not limited to, lawnmower type wheels, that are adjustable, for example, without limitation, in an up or down direction and a handle for moving the solar emergency power kit from one area to another. Yet other embodiments may be moved around by a standard handcart or may also be carried by the user with handles 109 that are provided.

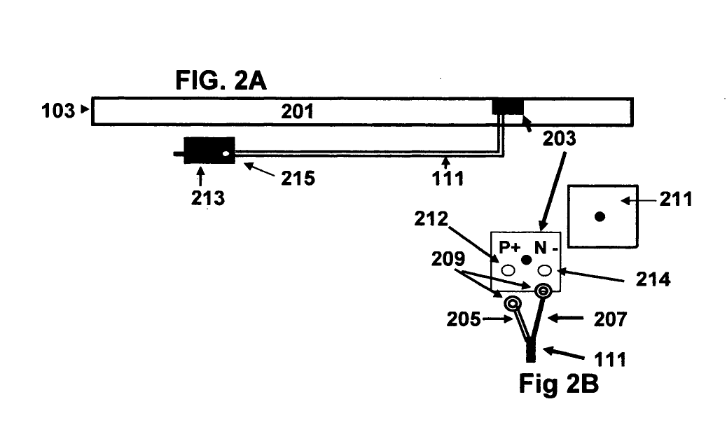

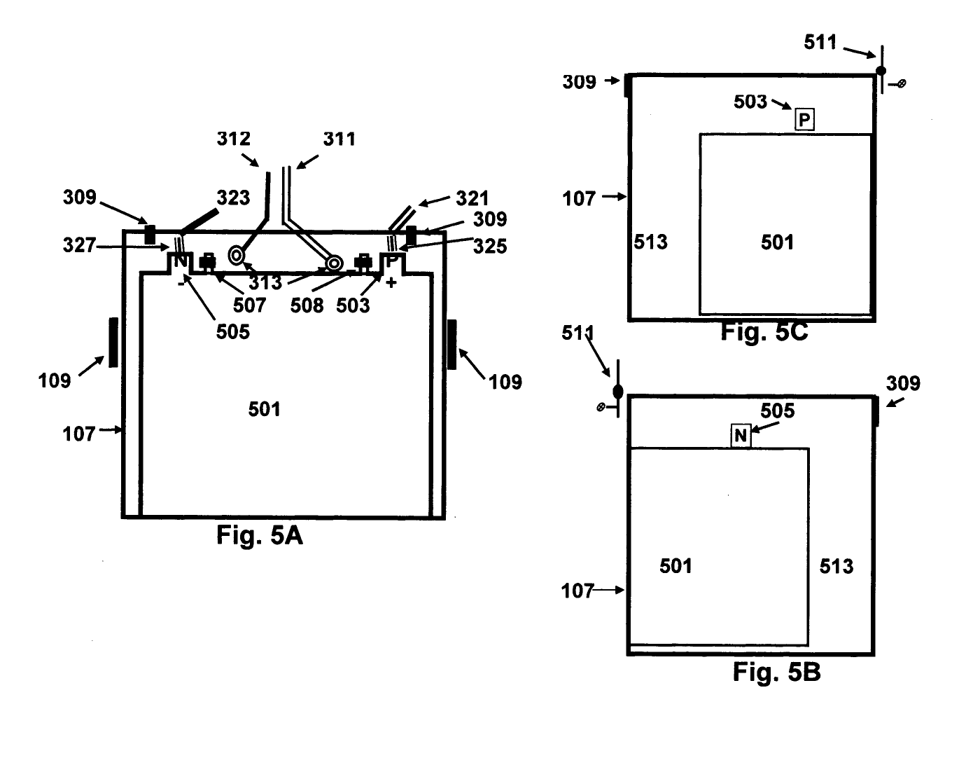

FIG. 2A is a schematic diagram of an exemplary solar panel assembly 103 for a solar emergency power kit, in accordance with an embodiment of the present invention. In the present embodiment, solar panel assembly 103 comprises a solar panel 201 and a solar panel connection box 203. Solar Panel 201 is preferably a 50-watt panel. However, alternate embodiments may use solar panels of various wattages depending on intended use. For example, without limitation, one embodiment may use a 10-watt solar panel for general battery maintenance and for use when short power outages occur, and embodiments with 50-watt solar panels maybe recommended for daily users. Solar panel connection box 203 connects solar panel assembly 103 to connecting cord 111. The other end of connecting cord 111 is connected to power adapter 113 located on upper box 105, shown by way of example in FIG. 1. This enables power from solar panel assembly 103 to be stored in a storage battery located in lower box assembly 107, shown by way of example in FIGS. 5A, 5B and 5C. In the present embodiment, power adapter 213 is a 12-volt adapter and has an indicator light 215. Indicator light 215 remains on as long as power adapter 213 is plugged in. This enables the user to find the device in the dark if necessary. Power adapter 213 may be attached to the end of connection cord 111 through various means including, but not limited to, screws, soldering, or push-in connections, depending on the type of power adapter being used.

FIG. 2B illustrates exemplary solar panel connection box 203 of solar panel assembly 103, in accordance with an embodiment of the present invention. To attach connecting cord 111 to solar panel connection box 203 in the present embodiment, an outer layer of connecting cord 111 is stripped to expose two inner wires, typically a white wire 205 and a black wire 207. Then, a wire connector 209 is attached to the end of each wire, 205 and 207. In the present embodiment, wire connectors 209 are ring connectors attached to the ends of wires 205 and 207 with a crimping tool. A cover 211 is removed from solar panel connection box 203. Then white wire 205 is connected to a positive connection screw 212 and black wire 207 is connected to a negative connection screw 214. Cover 211 is then replaced to protect solar panel connection box 203.

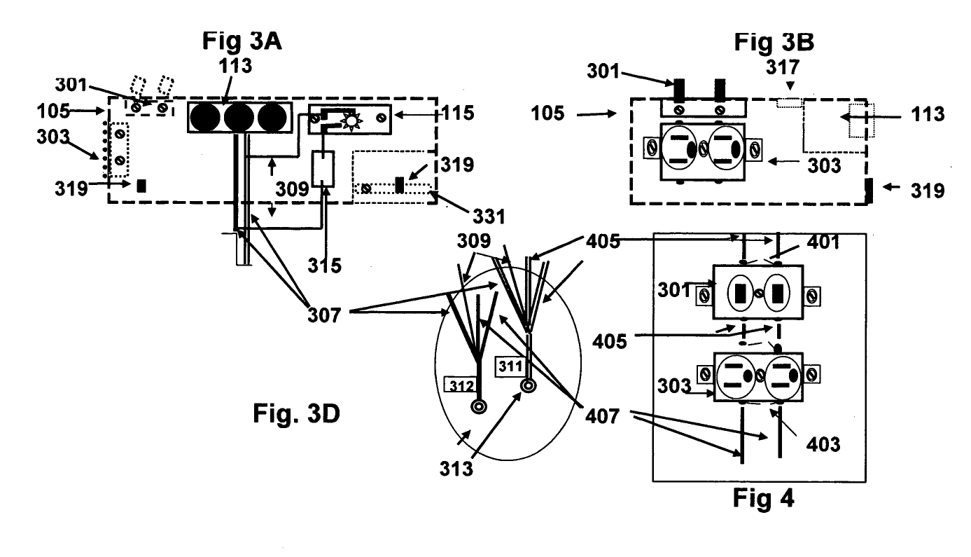

FIGS. 3A, 3B, 3C, and 3D are schematic diagrams of an exemplary upper box 105 of a solar emergency power kit, in accordance with an embodiment of the present invention. FIG. 3A is a front view, FIG. 3B is a left end view, and FIG. 3C is a right end view. FIG. 3D illustrates a close up view of an exemplary positive wire harness 311 and negative wire harness 312. In the present embodiment, upper box 105 comprises inlet/outlet power adapter 113, clearance light 115, a double switch 301, a receptacle 303, and a DC to AC inverter 305. Power adapter 113 is a triple 12-volt power inlet/outlet that enables power in and out at the same time. Power adapter 113 is attached to upper box 105 with a mounting bracket, and a stop block 317 is fastened to hold power adapter 113 in place. In the present embodiment, clearance light 115 has a clear lens and a dedicated switch 315 and is optional as a convenient night light. In alternate embodiments, the clearance light may be controlled by the main switch rather than a dedicated switch. In the present embodiment, switch 301 and receptacle 303 are covered with standard plastic covers with waterproof seals to protect the interior of the solar emergency power kit. Upper box 105 also comprises two upper latch assemblies 319. Upper latch assemblies 319 work in conjunction with lower latch assemblies on lower box 107, shown by way of example in FIGS. 5A, 5B and 5C to keep the solar emergency power kit in a closed position. In the present embodiment, upper latch assemblies 319 are located two inches from each side of the front of upper box 105.

In the present embodiment, inverter 305 is a 350-watt 12-volt DC to 120-volt AC inverter able to provide 120-volt electric power. Alternate embodiments may have larger inverters; however, larger inverter needs may require a larger solar panel. To determine these needs follow the selected manufacture's manual and warranty information. In the present embodiment, inverter 305 limits use of the reserve power in the storage battery. A positive inverter wire 321 and a negative inverter wire 323 connect inverter 305 to a positive alligator clip 325 and a negative alligator clip 327, respectively, on the storage battery. When inverter 305 is not in use it is preferable to disconnect positive inverter wire 321 and negative inverter wire 323 from positive alligator clip 325 and negative alligator clip 327 to avoid power loss. In the present embodiment, inverter 305 is attached to upper box 105 with a plywood support 331 using screws 333. Inverter 305 comprises features such as, but not limited to, a power switch 335, an on indicator light 337 and a low battery indicator light 339.

12-volt DC non-inverter wires 307 connect power adapter 113 to a storage battery, shown by way of example in FIGS. 5A, 5B, and 5C. Non-inverter wires 307 join with positive power wires 405, negative power wires 407, and clearance light wires 309 to form positive wire harness 31 1 and negative wire harness 312. In the present embodiment, wire harnesses 311 and 312 attach to the storage battery with ring wire connectors 313.

The electrical devices included on the front and left end of upper box 105 in the present embodiment, as shown in FIGS. 3A and 3B, are used for 12-volt applications. The configurations shown by way of example are normal to enable use with standard cords or items with 12-volt capabilities. The devices included on the right end of upper box 105 in the present embodiment, as shown in FIG. 3C, are intended for 120-volt applications. Standard 12-volt cords or other items may not be plugged into inverter 305.

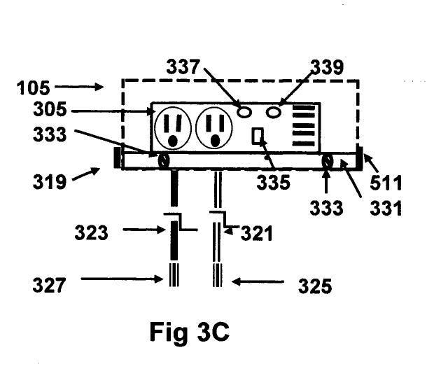

FIG. 4 illustrates exemplary wiring for switch 301 and receptacle 303 of upper box 105, in accordance with an embodiment of the present invention. In the present embodiment, switch 301 is a standard 120-volt, 15-amp double switch with a connection bridge 401 cut to form two separate switches, each side to operate one side of the separated receptacle 303. Receptacle 303 is a standard 120-volt, 15-amp receptacle with a connection bridge 403 cut to form two separate outlets. 120 volt devices cannot be powered direct from standard 12 volt receptacles. By not using a power inverter to convert to 120 V, longer use time is achieved for the system. Lighting applications would be achieved by removing the 120v bulb and installing a 12v bulb. Receptacle 303 is used for 12-volt operation with items such as, but not limited to, standard extension cords or table lamps with 12-volt bulbs plugged into receptacle 303. Inverter 305 requires more wattage for the same lighting needs. Positive power wires 401 connect switch 301 to the storage battery as part of positive wire harness 311, shown by way of example in FIG. 3D, and power wires 409 connecting switch 301 and receptacle 303 are both positive. Negative power wires 407 connect receptacle 303 to the storage battery as part of negative wire harness 312, shown by way of example in FIG. 3D. In the present embodiment, wire attachments are made with screws on switch 301 and receptacle 303 and wire connectors are not required.

FIGS. 5A, 5B and 5C are schematic diagrams of an exemplary lower box 107 of a solar emergency power kit, in accordance with an embodiment of the present invention. In the present embodiment lower box 107 houses a storage battery 501 and a storage area 513. Battery 501 is a 12-volt deep cycle battery of any type with a standard positive post 503 and a standard negative post 505. In the present embodiment, battery 501 also has secondary threaded negative post 507 and a secondary threaded positive post 508 with wing nuts for extra wire attachments. Lower box 107 also comprises handles 109, lower latch assemblies 509 and a hinge 511. Handles 109 are attached on opposing sides of lower box 107 and enable the device to be carried by the user. In the present embodiment, handles 109 are swing-out type handles attached with screws; however the handles may be various different types of handles and may be attached by varying means. For example, without limitation, one embodiment may have a plastic exterior with handles molded out of the same material built into the exterior of the device. In the present embodiment, lower latch assemblies 509 are located two inches from the sides of the front of lower box 107 to align with upper latch assemblies 319 on upper box 105, shown by way of example in FIGS. 3A, 3B and 3C. Those skilled in the art in light of the present teachings will recognize that various different types of latches may be used for upper and lower latch assemblies such as, but not limited to, draw latches, snap latches, hooks, or magnetic latches. In the present embodiment, hinge 511 attaches to the top of the back of lower box 107 and the bottom of the back of upper box 105 so that upper box 105 functions as a lid on lower box 107. In the present embodiment, hinge 511 is a 12-inch by 2-inch hinge attached by screws; however, in alternate embodiments different sizes of hinges and attachment means may be used.

To connect inverter 305, shown by way of example in FIG. 3C, to storage battery 501, positive inverter wire 321 is connected to positive alligator clip 325 on positive post 503, and negative inverter wire 323 is connected to negative alligator clip 327 on negative post 505. 12-volt DC non-inverter wires 307 connect power adapter 113, shown by way of example in FIG. 3A, to storage battery 501. Non-inverter wires 307 join with positive power wires 405, negative power wires 407, and a clearance light wire 309 to form positive wire harness 311 and negative wire harness 312. In the present embodiment, wire harnesses 311 and 312 attach to storage battery 501 with ring wire connectors 313 on secondary posts 507.

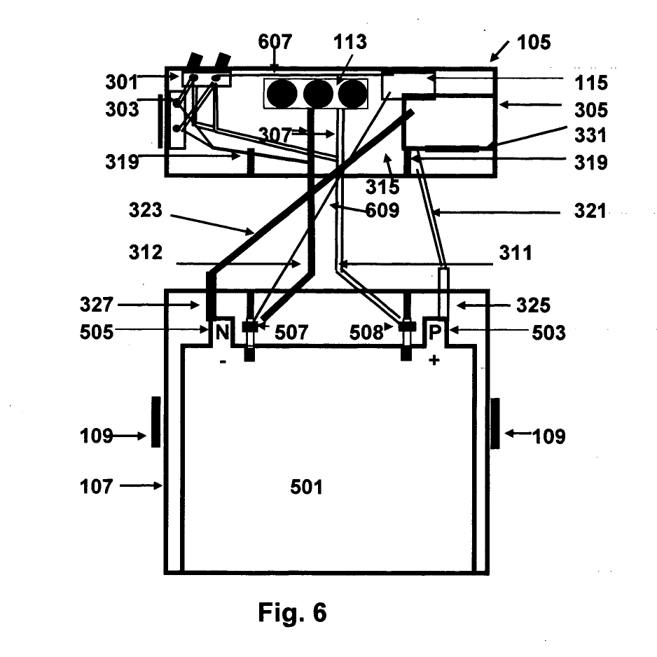

FIG. 6 is a schematic diagram of an exemplary assembly of upper box 105 and lower box 107 of a solar emergency power kit illustrating the connections between the devices in upper box 105 and storage battery 501 in lower box 107, in accordance with an embodiment of the present invention. In the present embodiment, inverter 305 connects to storage battery 501 by connecting positive inverter wire 321 to positive post 503 using positive alligator clip 325 and connecting negative inverter wire 323 to negative post 505 with negative alligator clip 327. The wires from adapter 113, switch 301 and receptacle 303 are bundled together into positive wire harness 311 and negative wire harness 312. These wire harnesses are connected to secondary posts 507 and 508 on storage battery 501. In the present embodiment a positive clearance light wire 607 from clearance light 115 is wired to switch 301 so that switch 301 controls clearance light 115, and a negative clearance light wire 609 connects directly to secondary post 507 near negative post 505. In alternate embodiments negative clearance light wire 609 may be bundled into negative wire harness 312, as shown by way of example in FIGS. 3A and 3D.

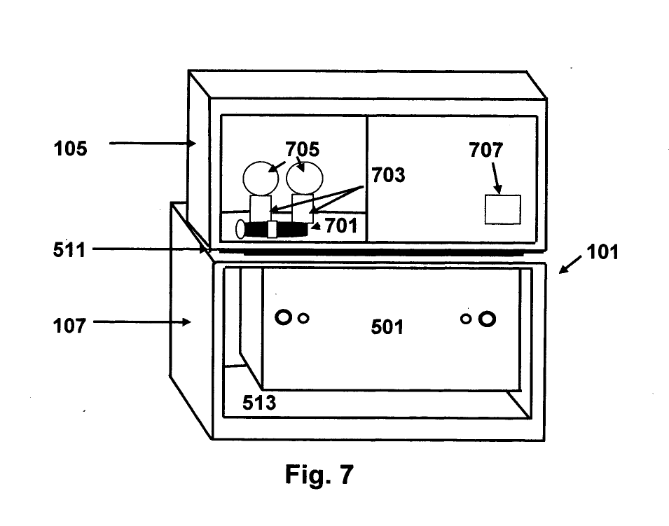

FIG. 7 is a top perspective view looking into an exemplary open solar emergency power kit 101 illustrating exemplary storage options, in accordance with an embodiment of the present invention. In the present embodiment, upper box 105 has a storage area for useful items in emergencies such as, but not limited to, the following items. The storage area may hold a two-AA battery standard flashlight 701, for example, without limitation, an LED AA flashlight, which can operate up to 250 hours between battery recharging. Flashlight 701 may be secured in upper box 105 with means such as, but not limited to, a clip or hook-and-loop material. The storage area also comprises two storage sockets 703 for standard 12-volt 50-watt bulbs 705. Sockets 703 enable bulbs 705 to be stored out of the way and help prevent breakage of bulbs 705. This type of bulb is usually found in RV or automotive departments and may be used in an emergency to replace 120-volt bulbs from a lamp. The storage area in the present embodiment also has a small plastic box 707 affixed to the top of the inside of upper box 105. Plastic box 707 is upside down when upper box 105 is closed onto lower box 107 so that it may be accessed when upper box 105 is opened by pivoting about hinge 511. Plastic box 707 may be used to store small items such as, but not limited to, extra wire connectors, ring type and standard push on and 20-amp buss fuses, which are replacement fuses for a 350-watt inverter.

In the present embodiment, lower box 107 also has a storage area 513 for useful items in emergencies. For example, without limitation, storage area 513 may hold a 25-ft, 16gage 2conducter indoor/outdoor extension cord that may be used for both 12-volt DC and 120-volt AC applications. Other smaller items may also be stored in storage area 513 such as, but not limited to, a set of small electrical alligator clips, rolls of electrical tape, a wire stripper, a small transistor radio with two AA rechargeable batteries, a battery post cleaning brush, and a AA/AAA battery charger along with batteries in charger that may be used in other battery operated items. Various other types of items may also be stored in the storage areas depending on the needs of the user and the capabilities of the particular embodiment. Furthermore, various embodiments may include more or less storage space.

In typical use solar emergency power kit 101 is used as a renewable power source in situations such as, but not limited to, emergencies or disasters, or while camping to operate12-volt or 120-volt low wattage items. The preferred embodiment is portable enough to be convenient for camping trips. Embodiment of the present invention may also be used by contractors to operate some non-continuous running low wattage items. However, a solar emergency power kit intended for contractor's use may require some modifications such as, but not limited to, Solar panel capacity should be increased to 100-200 watts, Inverter capacity 1000 watts or more. Battery capacity is increased either by using a double battery or the type used in trucks. Some of the items stored for emergencies may not be required, and its total weight would increase. However the current version may work in its present form for some contractors pending the type of work being done. Other versions may be designed according to type of work required. The preferred embodiment can also be recharged with a battery charger wherein a gage or voltage remaining indicator would be typically be necessary.

The preferred embodiment of the present invention is designed to operate all 12-volt electrical low wattage items plus some normal 120-volt household items. Thus, the preferred embodiment enables a user to use these items in a power outage caused by an event such as, but not limited to, an emergency or disaster. Furthermore, the power generated by the preferred embodiment is renewable, making camping and vacations more enjoyable as well. Some non-limiting examples of possible uses of solar emergency power kits according to embodiments of the present invention are as follows. A solar emergency power kit can operate household 120-volt lamps with an inverter or 12-volt lighting designed for camping uses. Some kitchen items such as, but not limited to, electric can openers, blenders and some mixers and other small appliances such as, but not limited to, electric razors and fans can be operated with a solar emergency power kit. For best efficiency it is recommended to run a 12-volt fan; however 120-volt fans can be operated with an inverter. Most of these fans require approximately 100 or more watts, plus the inverter load watt usage, combined this may require 150 watts per hour. Small TVs or DVD players designed to operate on AC-DC or rechargeable batteries can be powered by a solar emergency power kit; however some TVs will draw 50-watts or more per hour of power so the use of portable or battery operated TVs or DVD players is recommended for entertainment. A solar emergency power kit can recharge rechargeable batteries, from AA to D cell for devices such as, but not limited to, radios, flashlights, hand held games and rechargeable batteries for most cordless power tools, including, but not limited to, 18 to 24volt batteries. A solar emergency power kit can operate digital camera printers with a 120-volt inverter system and laptop computers with a 120-volt AC inverter or on 12-volts with a proper adapter. Smaller type electric 120-volt hand tools such as, but not limited to, some weed eaters and most home and garden tools up to 120-volt, 3-amp may be powered off of a solar emergency power kit. These tools may be used for activities such as, but not limited to, clearing a campsite. A solar emergency power kit can also recharge cell phones. Small refrigerators designed for 12-volt may be used during outings for example, without limitation, for those who may require medications that must be kept cool. All items that are designed to operate from a standard vehicle power outlet can also be operated by a solar emergency power kit according to an embodiment of the present invention.

The preferred embodiment is designed to operate table lamps and other low wattage household items for short periods. If an extension cord is required, it is recommend that the extension cord is no more than a standard 25-ft, 16gage 2conductor indoor/outdoor type cord. The preferred embodiment will however still work with longer cords at a reduced efficiency. Using low wattage, high efficiency light bulbs, to increase operating time is recommended. For example, without limitation, LED (Light Emitting Diodes) type light bulbs provide sufficient lighting at approximately 3 to 6 watts and are available in both 12-volt and 120-volt types. Using low wattage bulbs enables the user to operate additional items at the same time.

A solar emergency power kit has capabilities to operate any thing based on the limits of the inverter included in the particular solar emergency power kit. The more watts being used, the less operating time will be available. The only compensation is providing an offset by increasing the requirements of the solar panel; however, this only prolongs the use by simple math. For example, without limitation, if 350 watts are output, a 50-watt solar panel requires 7 hours to replace the 350 watts. If the user limits himself to 600 watts per night and no use during the day with a 50-watt panel, the user should not run out of power for weeks, if ever. Also, as days get longer, more solar panel input is available. Some daytime use may not affect recommended daily use. For example, without limitation, if the storage battery is at full charge, a user could watch a 50-watt AC-DC TV all day and not draw from the storage battery, if connected to a 50-watt solar panel, and thus still have a fully charged storage battery at the end of the day.

Understanding the number of watts used as output and the number of input watts determines the total daily use time available for a solar emergency power kit in accordance with an embodiment of the present invention. With continuous use without a solar panel, a battery similar to a storage battery used in a solar emergency power kit provides approximately 1350 watts of output. To maximize the number of watts of input, the solar panel should be facing the sun as much as possible during the day. Input cannot exceed total output capacity of the battery while not in use. It is recommended that the user finds some daily or weekly use for his solar emergency power kit. If everyone found some daily needed use for a solar emergency power kit, these kits would pay for themselves both environmentally and financially. It is also recommend that all recharging be done during daylight if needed, because this enables the solar panel to effectively restore as much power to the main storage battery and have all available batteries charged, including, but not limited to, cordless tool batteries.

In the preferred embodiment, the working electrical parts are contained in the upper box, lid portion of the solar emergency power kit. In some embodiments, the upper box may be removed and stored as a separate complete unit to be used in an emergency with most 12-volt car batteries. In these embodiments the upper box has means for removing the upper box from the lower box. For example, without limitation, in one embodiment instead of hinging on the lower box, the upper box slides over or into the lower box to form a lid that can be taken completely off of the lower box. In another embodiment, the upper and lower boxes may have no hinge and latches on multiple sides, for example, without limitation, two in the front and two in the back, which can be unlatched to remove the upper box from the lower box.

Alternate embodiments may use a larger solar panel and equivalent inverter to generate and store more power. Embodiments may be available as up-grades or down grades to the preferred embodiment to be suited to meet the needs of many individuals. For example, without limitation, a solar emergency power kit with a large solar panel and inverter may be used to power an entire house.

Another alternate embodiment of the present invention may be installed as a standard housing requirement to provide some emergency lighting and power. This application is on a similar scale to the preferred embodiment, not an expensive full house operation. This embodiment comprises identified and dedicated receptacles in desired rooms to be used as 12-volt lighting only that may be used if utilities are on or not. The present embodiment may be installed as a new home is built, or retrofitted to existing homes.

Although preferred embodiment is designed as a solar powered product it can also be recharged with a standard 12volt battery charger. This can be considered as a quick method to insure a full charge prior to a known possible power outage. Conventional systems are generally not rechargeable by way of solar power. This is done similarly as how a standard 12volt battery is recharged.

To upgrade or improve this unit is to add one of several types of means available to check the power level remaining in the battery. This is not limited to some of the more advanced gages or LED light strip indicating charged, low or needs recharged. Or something designed just for this application.

This allows the user to be aware of his CURRENT condition.

Another alternate application is to use a solar emergency power kit for limited outdoor lighting, for example, without limitation, in an out-of-the-way area in a back yard, or patio. This application provides power to an area with no electrical cord or wiring running to the area being powered.

Having fully described at least one embodiment of the present invention, other equivalent or alternative means for implementing a solar emergency power kit according to the present invention will be apparent to those skilled in the art. The invention has been described above by way of illustration, and the specific embodiments disclosed are not intended to limit the invention to the particular forms disclosed. The invention is thus to cover all modifications, equivalents, and alternatives falling within the spirit and scope of the following claims.

What is claimed is:

1. A portable power source kit for emergency and supplemental use, the kit comprising:
a lower box comprising a lower box volume;
a storage battery contained in said lower box volume;
an upper box comprising an upper box volume and attachable to said lower box;
a power adapter contained in said upper box volume, said power adapter comprising at least one or more inputs and at least one or more outputs, said power adapter electrically connected to said storage battery;
a power inverter contained in said upper box volume, said inverter electrically connected to said storage battery for providing DC to AC power conversion; and
a solar panel assembly electrically connected to said power adapter where said assembly provides power to said power adapter for use in charging said storage battery and delivering power to said one or more outputs.

2. The kit as recited in claim 1, wherein said upper box further comprises at least one or more DC power outlets.

3. The kit as recited in claim 2, wherein each of said one or more DC power outlets are connected to said storage battery via an outlet switch.

4. The kit as recited in claim 1, wherein said upper box further comprises a clearance light electrically connected to said storage battery via a switch.

5. The kit as recited in claim 4, where said switch is said outlet switch.

6. The kit as recited in claim 1, wherein said power inverter further comprises at least one or more AC power outlets.

7. The kit as recited in claim 6, wherein said power inverter is connected to said storage battery with clips for disconnecting when not in use to avoid power loss.

8. The kit as recited in claim 7, wherein said power inverter further comprises a power switch for activating said AC power outlets, an on indicator light and a low storage battery indicator.

9. The kit as recited in claim 1, wherein said upper box volume comprises a storage area for storing items.

10. The kit as recited in claim 1, wherein said lower box volume comprises a storage area for storing items.

11. The kit as recited in claim 1, wherein said lower box comprises handles on an exterior of said lower box for transporting the kit.

12. A portable power source kit for emergency and supplemental use, the kit comprising:
means for storing power;
means for containing said means for storing power;
means for providing DC inputs and DC outputs;
means for providing DC to AC power conversion;
means for containing said means for providing DC inputs and DC outputs and said means for providing DC to AC power conversion;
means for attaching said means for containing said means for storing power to said means for containing said means for providing DC inputs and DC outputs and said means for providing DC to AC power conversion;
means for providing a solar panel assembly; and
means for electrically connecting said means for storing power, said means for providing DC inputs and DC outputs, said means for providing DC to AC power conversion and said means for providing a solar panel assembly where said solar panel assembly provides DC power, DC power is provided at said DC outputs, power can be stored in said means for storing power and said DC to AC power conversion can be operative.

13. The kit as recited in claim 12, further comprising means for providing handles for the kit.

14. The kit as recited in claim 13, further comprising means for providing storage of items.

15. A portable power source kit for emergency and supplemental use, the kit comprising:
a lower box comprising a lower box volume;
a storage battery contained in said lower box volume;
an upper box comprising an upper box volume and attachable to said lower box;
a power adapter contained in said upper box volume, said power adapter comprising at least one or more inputs and at least one or more outputs, said power adapter electrically connected to said storage battery;
at least one or more DC power outlets, said DC power outlets being connected to said storage battery via outlet switches and said DC power outlets configured to provide DC power to standard AC devices that have been converted for DC use;
a clearance light electrically connected to said storage battery via a switch;
a power inverter contained in said upper box volume, said power inverter electrically connected to said storage battery for providing DC to AC power conversion, said power inverter comprising at least one or more AC power outlets, a power switch for activating said AV power outlets, an on indicator light and a low storage battery indicator; and
a solar panel assembly electrically connected to said power adapter where said solar panel assembly provides power to said power adapter for use in charging said storage battery and delivering power to said one or more outputs.

16. The kit as recited in claim 15, wherein said power inverter is connected to said storage battery with clips for disconnecting when not in use to avoid power loss.

17. The kit as recited in claim 16, wherein said storage battery is a 12-volt deep cycle storage battery.

18. The kit as recited in claim 17, wherein said upper box volume comprises a storage area for storing items.

19. The kit as recited in claim 18, wherein said lower box volume comprises a storage area for storing items.

20. The kit as recited in claim 19, wherein said lower box comprises handles on an exterior of said lower box for transporting the kit.
